(19) United States
(12) Patent Application Publication
(10) Pub. No.: US 2026/0008083 A1
(43) Pub. Date: Jan. 8, 2026

(54) Systems and Methods for Self-Cleaning Solar Panels Using an Electrodynamic Shield

(71) Applicant: The Research Foundation for the State University of New York, Albany, NY (US)

(72) Inventors: Alexander Orlov, Smithtown, NY (US); Shrish Patel, Aurangabad (IN); James F. Smith, Lake Wylie, SC (US)

(73) Assignee: The Research Foundation for the State University of New York, Albany, NY (US)

(21) Appl. No.: 19/173,209

(22) Filed: Apr. 8, 2025

Related U.S. Application Data
(63) Continuation of application No. 16/646,193, filed on Mar. 11, 2020, now Pat. No. 12,269,071.
(60) Provisional application No. 62/557,070, filed on Sep. 11, 2017.

(51) Int. Cl. B08B 6/00; B08B 17/06; B60S 1/02; B60S 1/56; B60S 1/62; H02S 40/10; H10F 19/80

(52) U.S. Cl. CPC B08B 6/00; B08B 17/06; B60S 1/02; B60S 1/56; B60S 1/62; H02S 40/10; H10F 19/807

(57) ABSTRACT

Systems and methods for self-cleaning a surface of an object where an electrodynamic shield is mounted to the surface. The electrodynamic shield includes one or more sets of electrodes atop a substrate, at least one or more sets of electrodes being covered in a protective film. A coating is applied to the top surface of the protection film. A signal pulse generator is connected to the one or more sets of electrodes, and generates a pulse signal that causes the one or more sets of electrodes to generate an electric field. The pulse signal comprises a plurality of different pulse signals which have phase differences between consecutive signals, and the electric field causes a particle atop the coating to experience an electrostatic force and be repelled away from the coating. These pulse signals can be tuned to increase efficiency of removal depending on dust type and relative humidity.

### CROSS-REFERENCE TO RELATED APPLICATIONS

This application claims is a continuation application of, and claims the benefit of priority to U.S. patent application Ser. No. 16/646,193 filed Mar. 11, 2020, now U.S. Pat. No. 12,269,071 issued Apr. 8, 2025, which is a U.S. National Phase Application under 35 U.S.C. § 371 of International Application No. PCT/US2018/050321 filed on Sep. 11, 2018, which claims the benefit of U.S. Provisional Patent Application No. 62/557,070 filed on Sep. 11, 2017, the entire disclosures of which are expressly incorporated herein by reference.

### BACKGROUND

### Technical Field

The present disclosure relates generally to equipment for cleaning solar panels. More specifically, the present disclosure relates to systems and methods for self-cleaning solar panels using an electrodynamic shield.

### Related Art

In the renewable energy field, solar power generation using solar panels has gained widespread interest and increased adoption. A major challenge with existing solar panels is the reduction of output power due to dust and other particles covering the solar panel. Dust deposition on the solar panels can significantly reduce power output. The standard approach to alleviate this problem is to mechanically clean the solar panels, which requires the use of water and manual labor, or water and very expensive and error-prone robotics. Emerging approaches include the application of either hydrophobic or hydrophilic coatings to glass surfaces of the solar panels, as well as using robots to automate manual cleaning. However, repetitive mechanical cleaning can damage the glass surfaces of the solar panels while requiring vast amounts of water, which is a scarce commodity in desert regions.

Further approaches include the use of an electrodynamic shield, or “EDS.” The EDS, via electrodes, generates an electric field that causes dust particles on the solar panels to experience an electrostatic force, and to be repelled from the solar panels. Use of the EDS has garnered interest in order to address dust accumulation problems on solar panels of vehicles operating on the Moon and on Mars. In the case of the Moon, a low gravity, zero magnetic field, and hard vacuum environment allow the EDS to repel dust particles. However, the EDS technique in its current embodiment is not practical for terrestrial applications, due to the Earth's humidity levels and low transparencies of electrode materials currently in use. Specifically, any layer of moisture condensing on the surface of the solar panel will shield the electric field and also act as a trap for dust particles due to the resistant forces of the moisture layer, such as dielectrophoresis forces, adhesion forces, etc. Further, with the current EDS systems, particles remain at the vicinities of electrode edges and at the middle position on top of the electrodes. These remaining particles are difficult to repel off the solar panel, even with additional electric field motivation. A combination of moisture and dust can also cause highly adhesive dust ‘cake’ formation, which is impossible to remove by the current EDS systems.

Accordingly, the systems and methods disclosed herein solve these and other needs by providing systems and methods for self-cleaning that do not require water or mechanical cleaning, and which addresses the moisture layer problem noted above. Specifically, the systems and methods disclosed herein solve these and other needs with a novel electrode and insulator configuration to control water adsorption, and with a novel electric pulse generator that improves cleaning efficiency and requires minimal power consumption.

### SUMMARY

This present disclosure relates to systems and methods for self-cleaning solar panels using an electrodynamic shield. The system includes an electrodynamic shield (“EDS”), which contains one or more sets of electrodes, a protective film on the electrodes, a coating atop the protective film, and a substrate below the electrodes. The electrodes and the protective film are shaped and arranged to control water adsorption on the surface of the electrodynamic shield. The substrate can be a low iron soda-lime glass cover of a solar panel, which is one of the most suitable types of glass for the EDS applications. A pulse signal generator can produce a pulse signal which powers the set(s) of electrodes. The pulse signal includes a plurality of different pulse signals which have phase differences between consecutive signals. The pulse signals can include different waveforms, amplitudes, and frequencies. The pulse signal can be enhanced by a leading-edge and trailing-edge pulses, if desired. The initial pulse can provide a measurable increase in force to overcome stiction and inertia of the fixed dust particle and to reduce the net power consumed by reducing the amplitude of the subsequent pulses. A combination of pulses can be tuned for specific types of dust. The pulse signal generator, when connected to a single electrode set, generates an electric field using a standing-wave signal pattern. When connected to multiple electrode sets, the pulse signal generator generates an electric field using a traveling-wave signal pattern. By powering the set(s) of electrodes, the EDS generates an electric field that causes dust particles on the coating to experience significant electrostatic force. The electrostatic force combined with gravity cause the dust particles to be repelled off the solar panel. The sequence of pulses, in combination with the hydrophobic nature of the top coating, loosen the dust particle from the dust cake on the solar panel, which is formed due to presence of moisture. Therefore, the EDS described in the invention can clean solar panels exposed to different types of dust and environmental conditions.

### BRIEF DESCRIPTION OF THE DRAWINGS

The foregoing features of the invention will be apparent from the following Detailed Description of the Invention, taken in connection with the accompanying drawings, in which:

FIG. 1 is a diagram illustrating the overall system of the present disclosure;

FIGS. 2-3 are diagrams illustrating the electrodynamic shield (“EDS”) of the present disclosure, integrated with a solar panel;

FIG. 4 is an illustration showing an example of the electrodes of the EDS arranged into two sets and connected to a pulse signal generator;

FIG. 5 is an illustration showing a cross-sectional view of the EDS of FIG. 4, including two sets of electrodes connected to the pulse signal generator generating a single standing-wave pulse signal;

FIG. 6 is an illustration showing an example of the electrodes of the EDS arranged into four sets and connected to a pulse signal generator;

FIG. 7 illustration showing a cross-sectional view of the EDS of FIG. 6, including four sets of electrodes connected to the pulse single generator which generates the traveling-wave pattern via the four separate pulse signals;

FIG. 8 is a schematic circuit diagram of the pulse signal generator of the present disclosure;

FIG. 9 is a diagram illustrating four different pulse signals generated by the system, wherein each pulse signal is shifted 900 in-phase signal;

FIG. 10 is a photo of oscilloscope traces of the four different pulse signals;

FIGS. 11A-B are diagrams showing dust particles being removed from the surface of the EDS;

FIG. 12 is a flowchart illustrating process steps carried out by the system of the present disclosure;

FIG. 13 is a diagram showing a cover with a power optimizer, a fixed base, a bypass connector, and a cover for a standard junction box;

FIG. 14 is a photo of a circuit implementation of the pulse signal generator; and

FIG. 15 is a diagram showing various types of dust that were tested.

### DETAILED DESCRIPTION

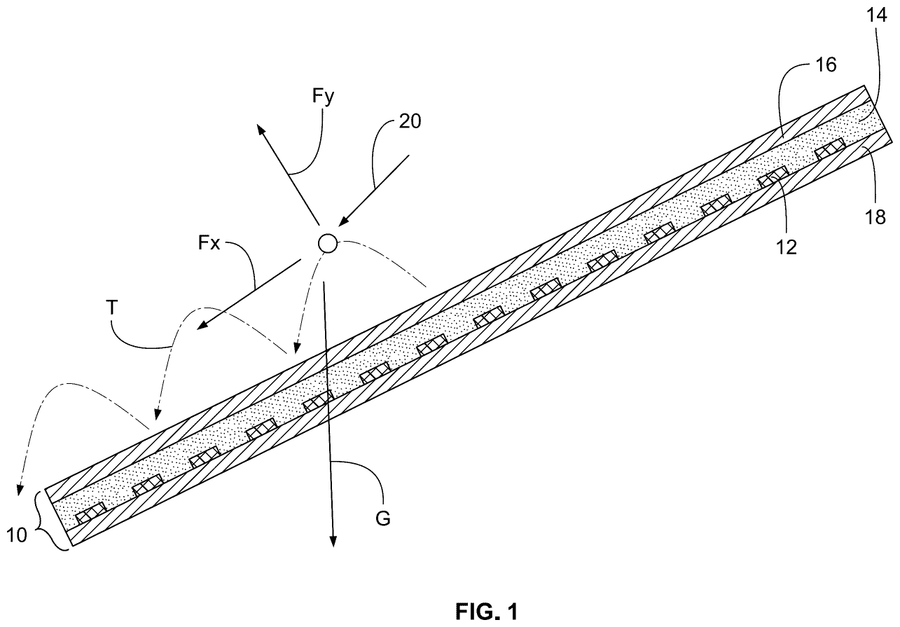

The present disclosure relates to systems and methods for self-cleaning solar panels using an electrodynamic shield, as described in detail below in connection with FIGS. 1-15.

It should first be noted that the systems and methods will be discussed below with reference to a solar panel. However, it is noted that the systems and methods of the present disclosure can be used with any system, including but not limited to, windows, vehicle surfaces, vehicle windshields, optical devices, etc., such that the electrodynamic shield allows for automatic cleaning of such objects.

FIG. 1 is a diagram illustrating the overall system, indicated generally at 10 (hereafter “electrodynamic shield 10” or “EDS 10”). The electrodynamic shield 10 includes one or more electrodes 12, a protection film 14, a coating 16, and a substrate 18. The electrodes 12 could be embedded within the protection film 14. The protection film is made of a material that prevents electrode breakdown. In an example, the protection film 14 is a transparent and highly dielectric silicon dioxide (“SiO₂”). SiO₂ prevents breakdown between the electrodes 12 at a high voltage. Further, SiO₂ protects the electrodes 12 from the environment and environmental elements. Specifically, the properties of SiO₂ allow for scratch resistance, moisture resistance, high transparency, etc. Those skilled in the art would understand that other materials can be used as the protection film 14, if desired, and may provide additional or different benefits.

The EDS 10 generates an electric field that causes dust particle(s) 20 to experience an electrostatic force with two vector component directions Fₓ and F_{y} and be repelled from the EDS 10. Gravitational forces G, which are continuously acting on the dust particle 20, help the dust particle 20 move towards the ground with a resulting particle trajectory T.

In a first example, the electrodes 12 are made of transparent Indium Tin Oxide (“ITO”). ITO is a transparent material with superior transparency, conductivity, and durability properties. The transparency of ITO can reach higher than 90%. In a second example, the electrodes 12 are made of Florine doped Tin Oxide (“FTO”). FTO is a transparent conductive oxide (“TCO”) of properties comparable to ITO. Those skilled in the art would understand that other transparent materials can be used to produce the electrodes, if desired, and may provide additional or different benefits.

In an example, the width of the electrodes 12 is in a range of 0.1 to 100 micrometers (“um”) and the inter-electrode spacing is in a range of 0.1 to 100 um. It should be noted that these ranges are only used as examples, and other ranges can be used. In another example, the width of the electrodes is in a range of 10 μm to 400 μm and the inter-electrode spacing is in a range of 10 μm to 800 μm. The geometry of the electrode is dependent upon the types of dust to be cleaned. For different types of dust, the efficiency depends upon different inter-electrode spacing and electrode shapes. The efficiency of the electrode is based on the balance between the sheet resistance and transparency of the electrodes.

The optically transparent coating 16 is applied to the top surface of the protection film 14. The coating 16 has one or more material properties, including but not limited to, anti-reflective properties, hydrophobic properties, etc. The material properties allow the coating to function efficiently under different conditions, such as, for example, high relative humidity. As such, the coating 16 enables the application of the EDS 10 in high humidity areas. The surface topology of the coating 16 can be altered to trap light inside and prevent loss of light due to reflection. One skilled in the art would understand how to tune the surface topology depending upon dust conditions in an applicable area.

The substrate 18 can be a rigid substrate and/or a flexible substrate. A flexible substrate can include flexible polymeric substrates such as an ethylene vinyl acetate (“EVA”) film, a polyethylene terephthalate (“PET”) film, a Polytetrafluoroethylene (“PTFE”) film, etc. The rigid substrate can include rigid low iron soda-lime glass substrates, solar panels, windows, automotive windshields, optical devices, and other substrates.

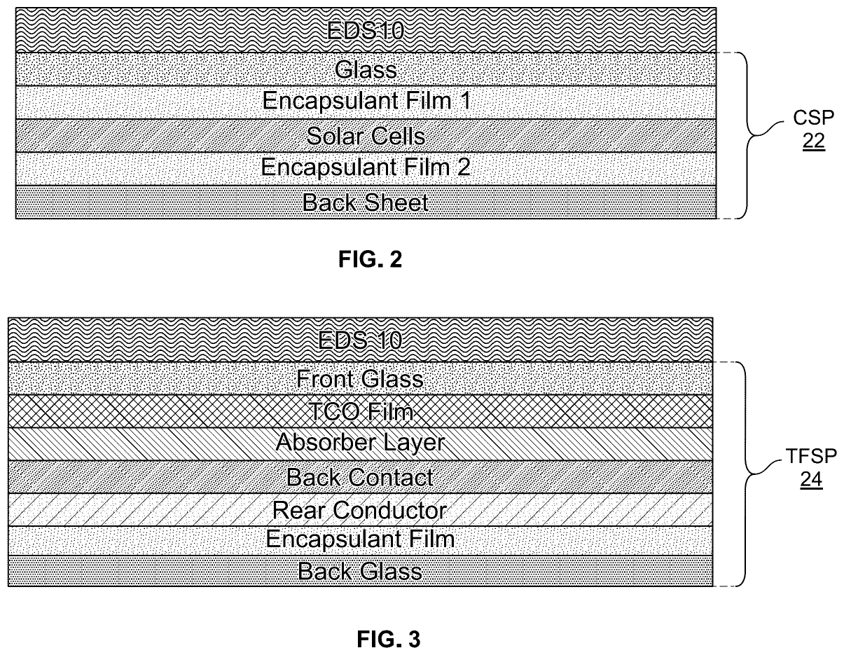

The EDS 10 is integrated with a solar panel. In an example, the EDS 10 can be integrated as the top layer of the solar panel. However, those skilled in the art would understand how to integrate the EDS 10 as any layer of the solar panel. FIG. 2 is an illustration showing the EDS 10 integrated with a crystalline solar panel (“CSP”) 22. FIG. 3 is an illustration showing the EDS 10 integrated with a thin film solar panel (“TFSP”) 24. It should be understood that the CSP and the TFSP are only examples of solar panels, and the EDS 10 can be integrated with any type of solar panel. It should also be understood that the EDS 10 is not limited to being used with only solar panels, and can be used with other applications, such as, but not limited to, windows, vehicle surfaces, vehicle windshields, optical devices, etc.

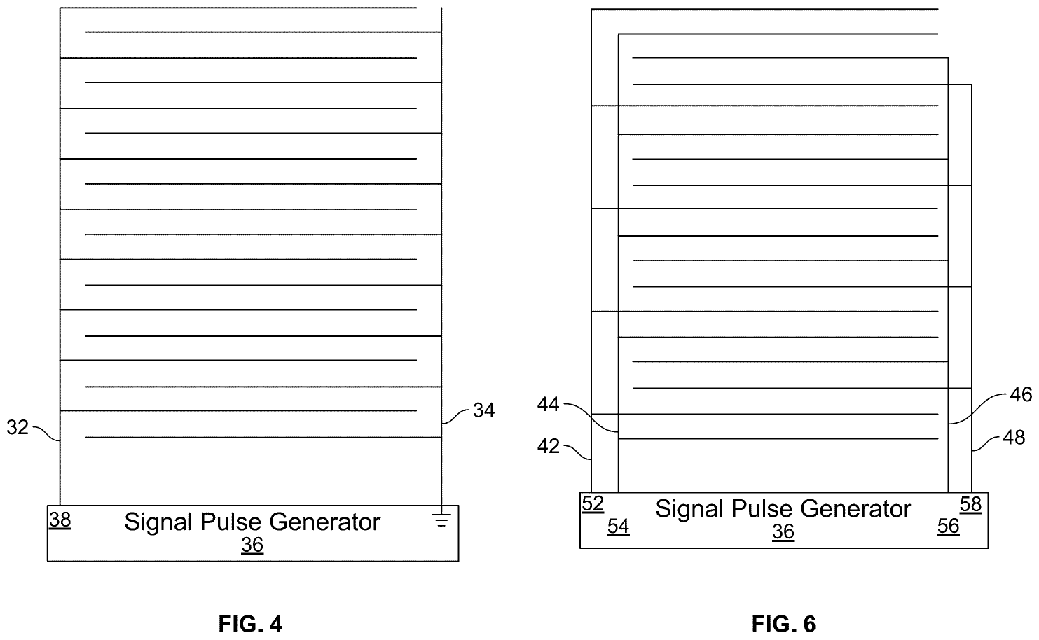

The electrodes 12 are grouped into one or more sets of electrodes. The one or more sets of electrodes can be organized into different configurations and connected to a pulse signal generator. Depending on the arrangement, different wave patterns can be generated in the electrode sets. FIG. 4 is an illustration showing a first example of the electrodes arranged into two sets 32, 34 and connected to a pulse signal generator 36. A pulse signal 38 from the pulse signal generator 36 powers the two sets of electrodes 32, 34 and generates a standing-wave pulse signal. More specifically, the pulse signal 38 powers the two sets of electrodes 32, 34 to generate an electric field that will charge the dust particles 20 and levitate them away (e.g., repel) from the surface of the EDS 10. It should be understood that solar panels are generally installed with a tilt angle (e.g., 25°-30°), and the gravitational force will aid in gliding the levitated dust particles 10 off the surface of the EDS 10.

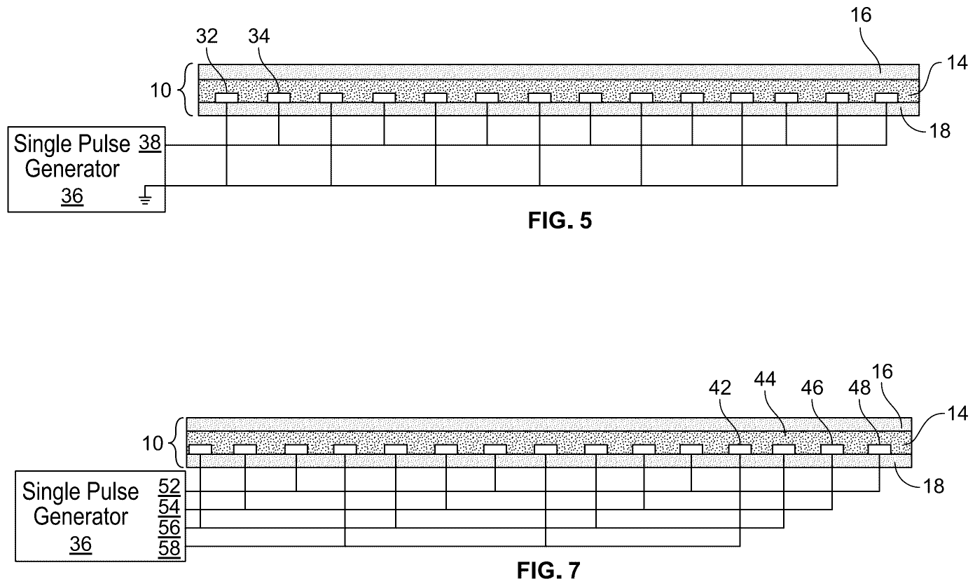

FIG. 5 is an illustration showing a cross-sectional view of the EDS 10 of FIG. 4, connected to the pulse signal generator 36 for generating a single standing-wave pulse signal. The EDS 10 also includes the coating 16 on the topmost surface, the protective film 14 used to prevent the electrodes 12 from the electrical breakdown, and the substrate 18 (e.g., a low iron soda-lime glass cover substrate of the solar panel).

FIG. 6 is an illustration showing a second example of the electrodes arranged into four sets 42, 44, 46, 48 connected to the pulse signal generator 36. A pulse signal from the pulse signal generator 36 powers the four sets of electrodes 42, 44, 46, 48 and generates a traveling-wave pattern. More specifically, the pulse signal powers the four sets of electrodes 42, 44, 46, 48 with four separate pulse signals 52, 54, 56, 58. The four separate pulse signals 52, 54, 56, 58 have phase differences of 90° between consecutive signals. This form of electrode arrangement (four sets of electrodes and a traveling-wave pattern) will slide the dust particles 20 towards the edge of the EDS 10 surface and onto the ground.

FIG. 7 is an illustration showing a cross-sectional view of the EDS 10 of FIG. 6, connected to the pulse single generator 36 which generates the traveling-wave pattern via the four separate pulse signals 52, 54, 56, 58. It should be understood that the generation of standing waves and traveling waves by the pulse signal generator is only by way of example, and the systems, methods, and embodiments discussed throughout this disclosure can generate and use other waves, such as, but not limited to, triangular waves, sine waves, saw-tooth waves, etc.

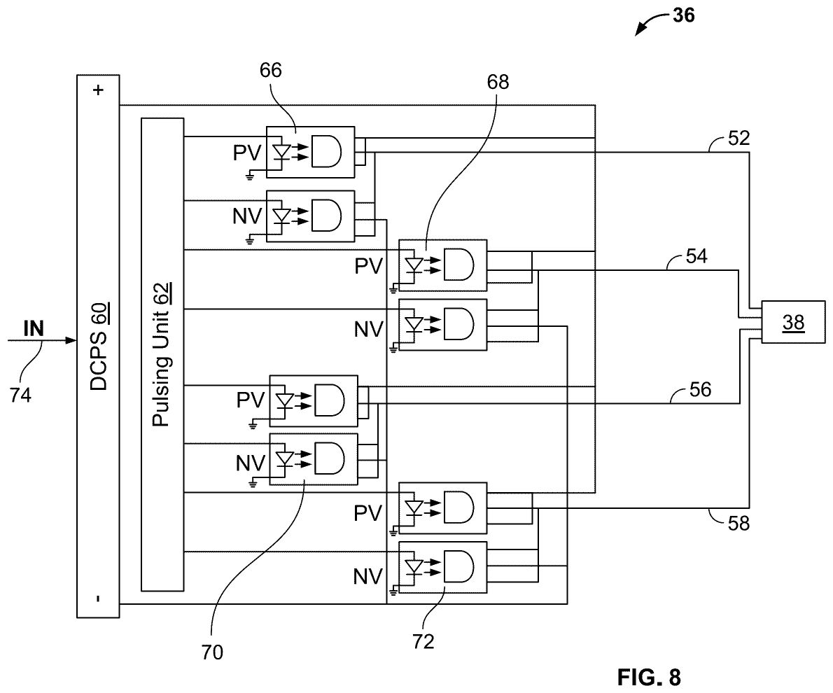

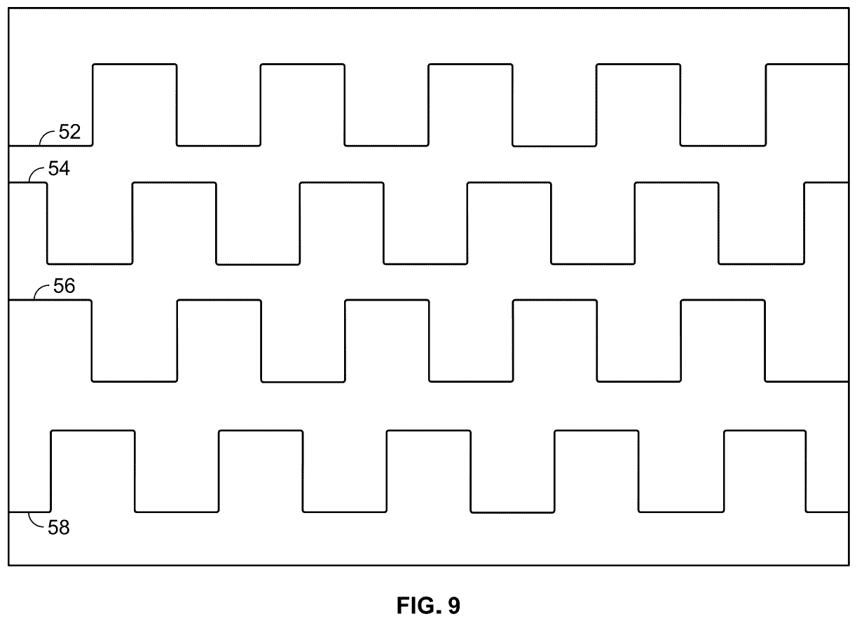

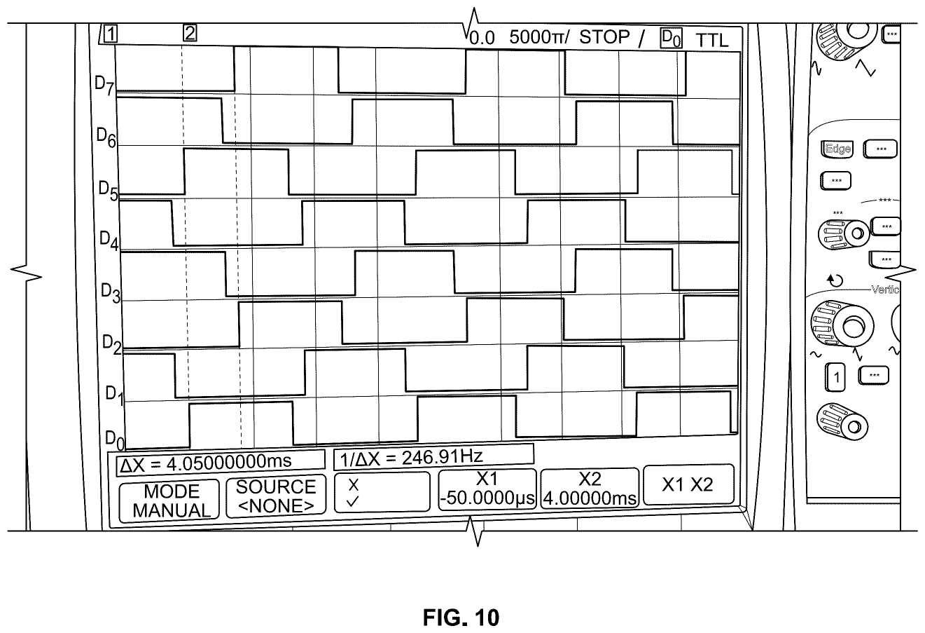

FIG. 8 is a schematic circuit diagram of the pulse signal generator 36. Specifically, the schematic diagram shows the pulse signal generator 36 generating four different pulse signals 52, 54, 56, 58, which have phase differences of 90° between consecutive signals. The pulse signal generator 36, when connected to a single electrode set (e.g., electrode set 32), as shown in FIG. 4, will generate an electric field using a standing-wave signal pattern. The pulse signal generator 36, when connected to the four electrode sets 42, 44, 46, 48, as shown in FIG. 6, will generate an electric field using a traveling-wave signal pattern. The circuit includes a DC power source (“DCPS”) 60, a pulsing unit 62, and four pairs of power switching transistors 66, 68, 70, and 72, which could also function as optoisolators for the pulsing unit 62. The DCPS takes power directly from a solar panel as an input 74. The pulsing unit is a computing module that provides commands to the transistors. Each pair of power switching transistors has a transistor to switch the positive voltage (“PV”) and another is to switch negative voltage (“NV”). The pulse signal 38 can be a square wave of an amplitude of each signal up to a certain voltage. For example, the pulse signal 38 can be a square wave of an amplitude of each signal up to 1500V. FIG. 9 is an illustration showing the different pulse signal 52, 54, 56, and 58 with each pulse signal being shifted 900 in phase compared to a consecutive signal. FIG. 10 is a photo of four different pulse signals 52, 54, 56, and 58.

Referring back to FIG. 8, the sets of electrodes are powered by the pulse signals 38 or 52, 54, 56 and 58. The pulse signals produce an electrical field on the surface of the coating 16 and remove the particles from the surface of the solar panel. The pulse signals, when connected to a different arrangement of the sets of electrodes, will remove particles via a different methodology. Furthermore, the EDS 10 containing an arrangement of two sets of electrodes 32, 34, as illustrated in FIG. 5, will levitate the dust particles away from the surface of the EDS 10 in a hopping manner and the dust particles will reach the ground will the aid of the gravitational force. The EDS 10 containing the arrangement of four sets of electrodes 42, 44, 46, 48, as illustrated in FIG. 7, slides the dust particles in a traveling manner towards the edge of the panel, and the dust particles will fall on the ground. This eliminates or greatly reduces the need for gravitational assistance. In this manner, substrate surfaces perpendicular to the force of gravity can also be cleaned.

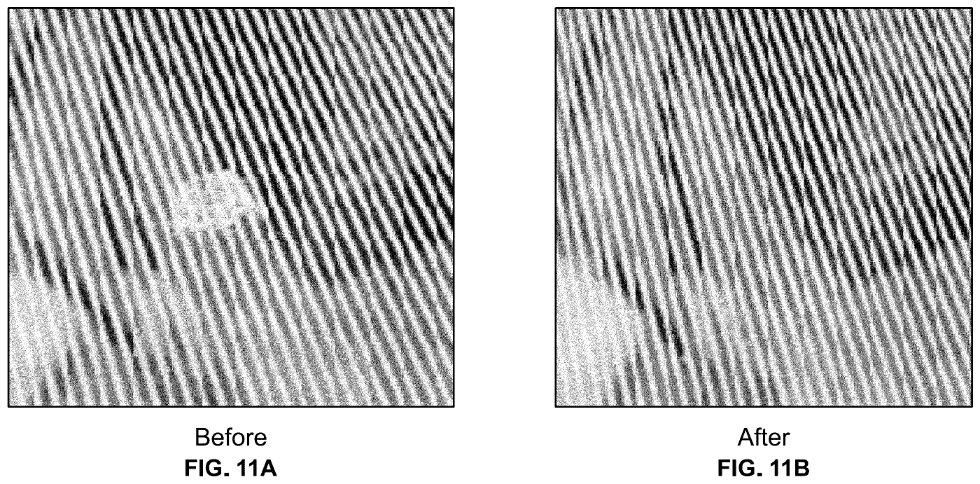

The pulse signal generator 36 can adjust the signal parameters of the pulse signals. The signal parameters include an amplitude of the signal, a frequency of the signal, etc. The amplitude of the signal and the frequency of the signal required to clean the dust particles 20 are determined by the properties of the dust particles 20, such as, but not limited to, a dust particle size, a dust particle chemical composition, and a dust particle surface charge density. Adjusting the signal parameters adjusts the electric field strength, which removes the dust particles from the surface of the EDS 10. Specifically, the electric field strength is adjusted based on the amplitude of the pulse signals, and the particle charging and removing process is adjusted based on the frequency of the pulse signals. In an example, the amplitude is in a range between 400-1000 volts and the frequency is in a range from 30 to 100 Hz. It should be understood that other ranges can also be used. FIGS. 11A-11B illustrate dust particles being removed from the surface of the EDS 10.

It should be understood that the electrostatic force that moves the dust particles grows as the dust particle size increases and is very weak for a dust particle with a small size, which makes removal of the ultra-fine particle difficult. Therefore, the dust particle size is required to grow by accretion before switching on the electrostatic force. The electrostatic force acting on the dust particle mainly depends on its size and the gradient of the square of the magnitude of the electric field. In an example, increasing the electrostatic force acting on the dust particle improves the gradient of the square of the magnitude of the electric field by enhancing the strength of the electric field. The electric field strengths can be achieved by integrating microelectrodes with smaller size and, as a result, a low voltage is so strong that the range of the controllable particle size is expanded gradually.

It should further be understood that, for better efficiency, the size of the dust particles should be less than the inter-electrode spacing. The electrode 12 width and inter-electrode separation should be on the scale of the smallest dust particle. Therefore, EDS 10 being constructed with smaller electrode width and inter-electrode spacing in the range of 10 to 100 um can be more efficient for a fine dust particle in the range of 5-100 um.

In addition to reducing the electrode gap, insulating microstructures can enhance the strength of the electric field as well. As compared to traditional electrode-exposed devices, external electrodes can be employed to generate a uniform electric field, and insulating microstructures can be embedded into microchannel to squeeze the electric field. Thereby, a high electric field gradient with a local maximum is created. The high electric field gradient has advantages in that the structure is mechanically robust and chemically inert, and a very high electric field may be applied without air breakdown discharge or arcing happening at 3 V/um at STP. While the traditional electrode-based devices use small amplitude AC signals, high amplitude DC voltages pulses can be directly applied to blocks to squeeze electric field to steer the electric field gradient to have a parallel component to the substrate instead of perpendicular to the substrate.

The dust deposition rate in a typical solar power plant located in the desert region is 0.3-0.5 g/m² per day. The deposited dust hinders the light reaching a solar cell(s) on the solar panel. Automated dust removal of dust can be performed with the addition of a sensor which responds to the loss of light reaching the solar cell. An activation system, which includes the sensor, can be programmed to activate the pulse signal generator 36 when the sensor detects a predetermined drop in light intensity reaching the solar panel and direct a small amount of power from the solar cell to the pulse signal generator 36 to generate the pulse signals.

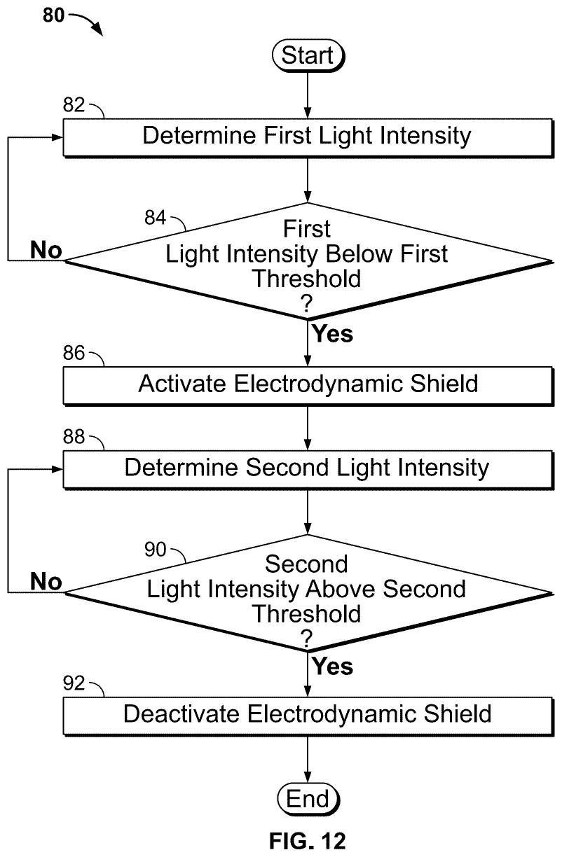

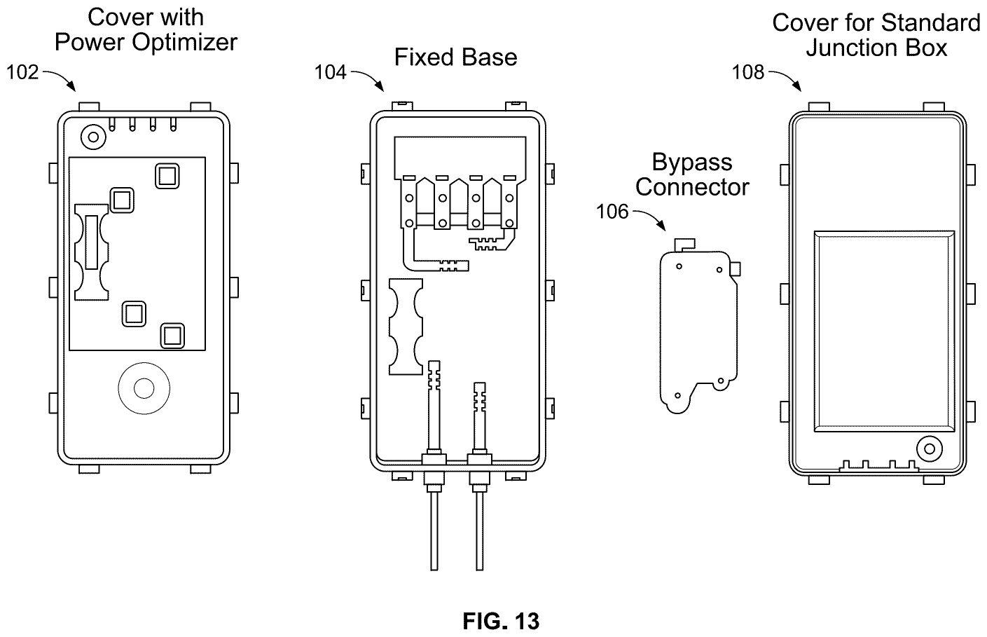

FIG. 12 is a flowchart illustrating process steps carried out by the system of the present disclosure, indicated generally as method 80. In step 82, the system determines a first light intensity, where the first light intensity is an amount of light reaching the solar cell. In step 84, the system determines whether the first light intensity is below a first predetermined threshold. When the first light intensity is not below the first predetermined threshold, the system proceeds to step 82 to again determine the first light intensity. The system can again determine the first light intensity immediately, or after a predetermined time delay. When the first light intensity is below the first predetermined threshold, the system proceeds to step 86, where the system activates the EDS 10. The EDS 10, as discussed above, produces an electrical field on the surface of the coating 16 and removes the dust particles from the surface of the solar panel. In step 88, the system determines a second light intensity. In step 90, the system determines whether the second light intensity is below a second predetermined threshold. The second predetermined threshold can have the same value as the first predetermined threshold, or a different value. When the second light intensity is below the predetermined threshold, the system proceeds to step 88, and, again determines a second light intensity. The system can again determine the second light intensity immediately, or after a predetermined time delay. When the second light intensity is no longer below the second predetermined threshold, the system proceeds to step 92, where the system deactivates the EDS 10.

It should be noted that the electrodes 12 could be activated by either using a standing wave pulse signal or traveling wave pulse signal. Newer generation solar modules are optionally integrated with a power optimizer during the manufacturing process. The circuit used to activate electrodes can be incorporated into the already existing power optimizer device with the few additional steps during the manufacturing process of the solar panels.

The power optimizers have the ability to change the voltage or current to reduce system losses and have similar electronic functions that could be extended to incorporate the control in FIG. 8. The other devices are string inverters and micro-inverters. Inverters convert direct current (“DC”) energy generated by the solar panels into usable alternating current (“AC”) energy. Micro-inverters and power optimizers are often collectively referred to as Module-Level Power Electronics or MLPEs. MLPE technologies are rapidly gaining popularity and market share as their costs have come down.

Power optimizers are located at each panel, usually integrated into the panels themselves. However, instead of converting the DC electricity to AC electricity at the panel site, the DC electricity is conditioned, energy loss optimized and sent to a string or central inverter. This approach results in higher system efficiency than a string inverter alone. It also reduces the impact of individual or sectional panel shading on system performance and offers panel performance monitoring.

The AC/DC converter can be connected by installers to each solar panel or embedded by module manufacturers, replacing the traditional solar junction box. As such, the circuit shown in FIG. 8 can be directly integrated into the power optimizer for the newer solar panel or into the junction box for the regular solar panel. This integration of the circuit into the junction box enclosure and power optimizer that is already embedded into at the back of the solar panel will also provide protection for water and dust ingression. Moreover, the junction box is typically IP67 certified, which ensures safe operation even in a harsh condition such as dust storm, high temperature, and high humidity. FIG. 13 is an illustration showing a cover with a power optimizer 102, a fixed base 104, a bypass connector 106, and a cover for a standard junction box 108. As discussed above, the circuit shown in FIG. 8 can be directly integrated into the power optimizer 102 or into the fixed base 104, and covered by the standard junction box cover 108.

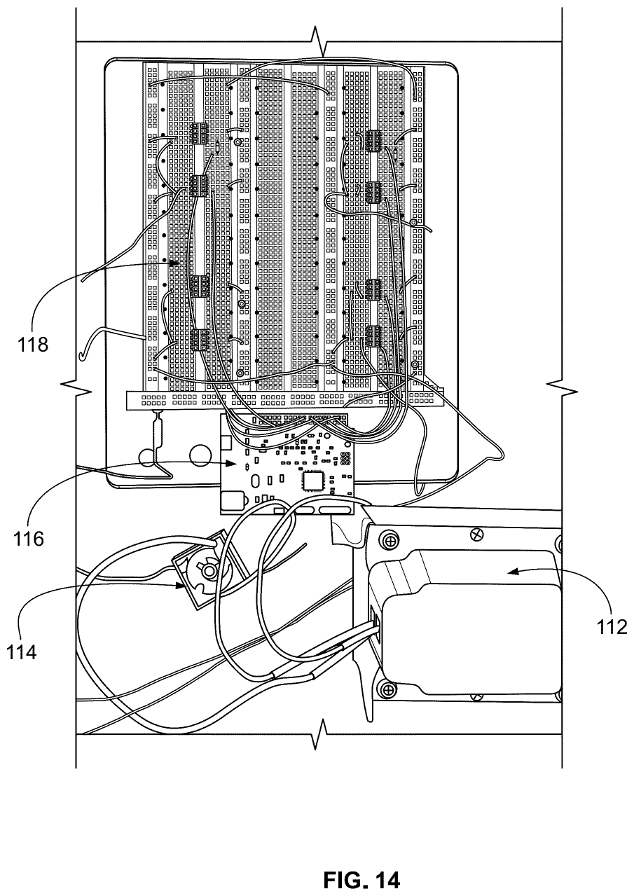

FIG. 14 is a photo showing a circuit implementation of the pulse signal generator. As can be seen, FIG. 14 includes a transformer, a bridge rectifier 114, a microcontroller board 116, and a plurality of integrated circuits and discrete components on a breadboard 118. The circuit implementation can be integrated into integrated into the power optimizer 102 or into the fixed base 104 of FIG. 13.

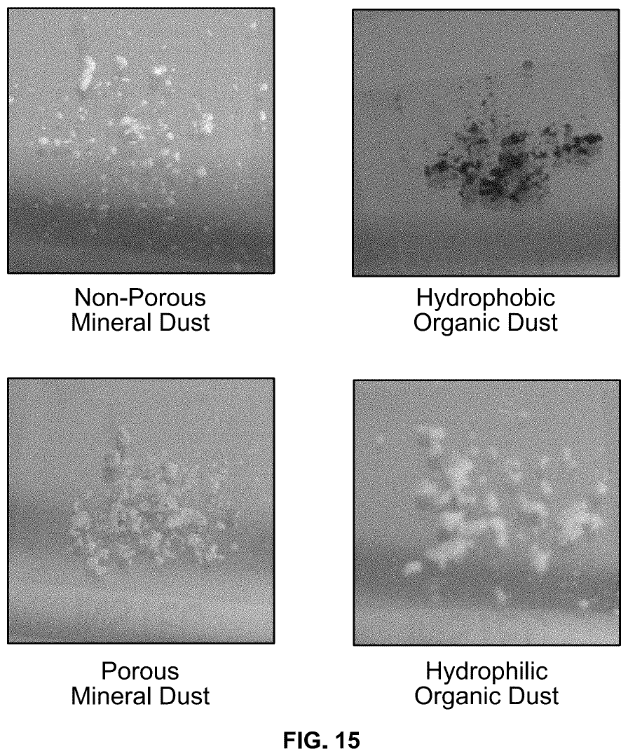

FIG. 15 is a photo showing various types of dust used for testing, including: non-porous mineral dust, porous mineral dust, hydrophobic organic dust, and hydrophilic organic dust. It was discovered that different types of dust require a different combination of amplitude, phase shifts and frequency of the pulse signal. The coating 16 with the hydrophobic properties helps the EDS 10 to clean even the most hygroscopic dust.

Having thus described the system and method in detail, it is to be understood that the foregoing description is not intended to limit the spirit or scope thereof. It will be understood that the embodiments of the present disclosure described herein are merely exemplary and that a person skilled in the art can make any variations and modification without departing from the spirit and scope of the disclosure. All such variations and modifications, including those discussed above, are intended to be included within the scope of the disclosure. What is intended to be protected by Letters Patent is set forth in the following claims.

1. (canceled)

2. A method for self-cleaning a surface of an object using an electrodynamic shield, comprising:
generating, by a pulse signal generator, a pulse signal through one or more sets of electrodes atop a substrate, the at least one or more sets of electrodes being covered in a protective film, and a coating being applied to the top surface of the protection film, wherein:
the pulse signal causes the one or more sets of electrodes to generate an electric field;
the pulse signal comprises a plurality of different pulse signals which have phase differences between consecutive signals; and
wherein the electric field causes a particle atop the coating to experience an electrostatic force and be repelled away from the coating.

3. The method of claim 2, further comprising:
determining, by an activation subsystem, a light intensity, wherein the light intensity is an amount of light reaching a solar cell; and
activating the signal pulse generator when the light intensity falls below a predetermined threshold.

4. The method of claim 2, wherein when the pulse signal generator is connected to a single electrode set of the one or more sets of electrodes, the pulse signal generator generates an electric field using a standing-wave pulse signal.

5. The method of claim 2, wherein when the pulse signal generator is connected to four electrode sets of the one or more sets of electrodes, the pulse signal generator generates an electric field using a traveling-wave signal pattern.

6. The method of claim 2, wherein an amplitude of the pulse signal is in a range between 400-1000 volts, and a frequency of the pulse signal is in a range of 30-100 Hertz.
